(19) United States
(12) Patent Application Publication
(10) Pub. No.: US 2015/0084076 A1
(43) Pub. Date: Mar. 26, 2015

(54) Light Emitting Module and Lighting Device

(71) Applicant: Toshiba Lighting & Technology Corporation, Yokosuka-shi (JP)

(72) Inventors: Tsuyoshi Oyaizu, Yokosuka-shi (JP); Yoshiko Takahashi, Yokosuka-shi (JP); Masahiro Fujita, Yokosuka-shi (JP)

(73) Assignee: Toshiba Lighting & Technology Corporation, Yokosuka-shi (JP)

(21) Appl. No.: 14/219,451

(22) Filed: Mar. 19, 2014

(30) Foreign Application Priority Data
Sep. 20, 2013 (JP) 2013-196120

(51) Int. Cl. H01L 33/58

(52) U.S. Cl. CPC H01L 33/58
USPC 257/98

(57) ABSTRACT

According to one embodiment, a light emitting module includes: a semiconductor light emitting element and an incident suppression section. The semiconductor light emitting element includes a base material and a light emitting layer. The base material is formed of a material absorbing light and is provided on a substrate. The light emitting layer is provided on the base material and emits the light. The incident suppression section is provided around the base material and suppresses light among the light that is emitted from the light emitting layer from being incident on the base material.

### CROSS-REFERENCE TO RELATED APPLICATIONS

This application is based upon and claims the benefit of priorities from Japanese Patent Application No. 2013-196120 filed on Sep. 20, 2013; the entire contents of which are incorporated herein by reference.

### FIELD

Embodiments described herein relate generally to a light emitting module and a lighting device.

### BACKGROUND

In recent years, a lighting device of which a light source is a Light Emitting Diode (LED) is widespread. As the LED that is used in such a lighting device, for example, an LED having a structure is known in which a semiconductor layer (a light emitting layer) including GaN or the like is provided on a transparent base material such as sapphire and the semiconductor layer is covered by a resin including the phosphor.

In the LED having such a structure, light that is emitted from the light emitting layer may be reflected from a boundary surface of the resin and may be incident on the base material or the light that is generated in the phosphor that is excited by the light emitted from the light emitting layer may be incident on the base material. However, even in this case, since the base material is transparent, the light that is incident on the base material is transmitted through the base material and is reflected by the substrate or the like and then is emitted to the outside of the LED.

However, in a case of the LED in which a black member such as silicon is used as the base material, the light that is incident on the base material is absorbed by the base material and is not emitted to the outside of the LED. Thus, if the silicon is used in the base material, luminous efficiency of the entire LED is lowered.

### BRIEF DESCRIPTION OF THE DRAWINGS

FIG. 1 is a perspective view illustrating an example of a lighting device according to a first embodiment.

FIG. 2 is a cross-sectional view of an example of the lighting device according to the first embodiment.

FIG. 3 is a conceptual view illustrating an example of an electrical connection relationship of the lighting device according to the first embodiment.

FIG. 4 is a view illustrating an example of a configuration of a light emitting unit according to the first embodiment.

FIG. 5 is a top view illustrating an example of a light emitting module according to the first embodiment.

FIG. 6 is a cross-sectional view of the light emitting module along A-A in FIG. 5.

FIG. 7 is an enlarged view of the vicinity of an LED in FIG. 6.

FIG. 8 is a top view illustrating an example of a light emitting module according to a second embodiment.

FIG. 9 is a cross-sectional view of the light emitting module along B-B in FIG. 8.

FIG. 10 is an enlarged view of the vicinity of an LED in FIG. 9.

FIG. 11 is a top view illustrating an example of a light emitting module according to a third embodiment.

FIG. 12 is a cross-sectional view of the light emitting module along C-C in FIG. 11.

FIG. 13 is a cross-sectional view illustrating an example of a light emitting module according to a fourth embodiment.

FIG. 14 is a view illustrating an example of the vicinity of an LED according to a fifth embodiment.

FIG. 15 is a view illustrating an example of the vicinity of an LED according to a sixth embodiment.

FIG. 16 is a view illustrating an example of the vicinity of an LED according to a seventh embodiment.

### DETAILED DESCRIPTION

In view of the problems of the related art, it is an object of the present invention to improve the luminous efficiency of the LED.

According to an embodiment described below, a light emitting module includes: an LED that is an example of a semiconductor light emitting element configured to include a base material that is formed of a material absorbing light and is provided on a substrate, and a light emitting layer that is provided on the base material and emits the light; and an incident suppression section configured to be provided around the base material and suppress light among the light that is emitted from the light emitting layer from being incident on the base material. According to the configuration, since even if the base material having low translucency and reflectance of the light is used, the light is suppressed from being incident on the base material, and it is possible to expect improvement in luminous efficiency as an entirety of the LED.

Further, in the light emitting module according to the embodiment described below, the incident suppression section may be white adhesive that bonds the base material on the substrate and the adhesive may be in contact with side surfaces of the base material so as to cover the side surfaces of the base material. Therefore, the light is suppressed from being incident on the base material with low cost and it is possible to expect that the light that is incident on the direction of the base material is reflected to the outside of the LED.

Further, in the light emitting module according to the embodiment described below, the adhesive may cover an area of half or more of the side surfaces of the base material. Therefore, it is possible to expect improvement in luminous efficiency of the entirety of the LED.

Further, in the light emitting module according to the embodiment described below, in a state where the adhesive bonds the base material and the substrate, a length of the adhesive around the base material in a thickness direction of the substrate may be greater than a length that is obtained by adding a thickness of the base material and a thickness of the light emitting layer. Therefore, it is possible to improve the luminous efficiency as the entirety of the LED and it is possible to expect that light distribution of the entirety of the LED is controlled by a smaller device.

Further, in the light emitting module according to the embodiment described below, the incident suppression section may be a substrate that has a concave section into which the base material is fitted. Further, at least a part of the inner wall of the concave section may be white. Therefore, the light is suppressed from being incident on the base material with low cost and it is possible to expect that the light incident on the direction of the base material is reflected to the outside of the LED.

Further, in the light emitting module according to the embodiment described below, a length of the concave section in the thickness direction of the substrate may be longer than a length of half of a thickness of the base material. Therefore, it is possible to expect improvement in luminous efficiency as the entirety of the LED.

Further, in the light emitting module according to the embodiment described below, the length of the concave section in the thickness direction of the substrate may be longer than a length that is obtained by adding the thickness of the base material and the thickness of the light emitting layer. Therefore, it is possible to improve the luminous efficiency as the entirety of the LED and to expect that the light distribution of the entirety of the LED is controlled by a smaller device.

Further, in the light emitting module according to the embodiment described below, the base material may have silicon. Further, a lighting device according to an embodiment described below may include the light emitting module described above and a lighting-on device configured to supply electric power to the light emitting module.

Hereinafter, the light emitting module and the lighting device according to the embodiments are described with reference to the drawings. Moreover, in the embodiments, the same reference numerals are given to configurations having the same functions and duplicate descriptions are omitted. Further, the light emitting module and the lighting device described in the embodiments below are illustrated as only an example and do not limit exemplary embodiments. Further, the embodiments described below may be appropriately combined within a range that is not inconsistent.

### First Embodiment

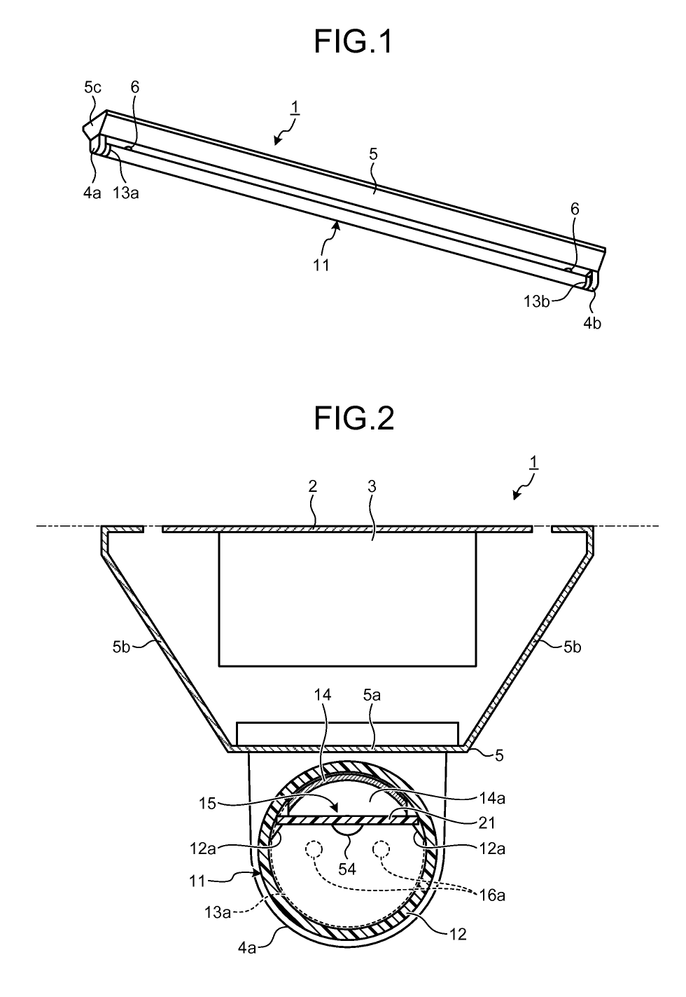

Hereinafter, a straight tube type lamp and a lighting device including the straight tube type lamp of a first embodiment, for example, a lighting apparatus, are described with reference to FIGS. 1 to 6.

### Configuration of Lighting Device 1

FIG. 1 is a perspective view illustrating an example of the lighting device according to the first embodiment. FIG. 2 is a cross-sectional view of the lighting apparatus illustrated in FIG. 1. In FIGS. 1 and 2, a numeral 1 illustrates a direct-mounted type lighting device.

The lighting device 1 includes a device body (an apparatus body) 2, a lighting-on device 3, a pair of first socket 4a and second socket 4b, a reflection member 5, a straight tube type lamp 11 that is an example of a light source device, and the like.

The body 2 illustrated in FIG. 2 is, for example, made of a metal plate having an elongated shape. The body 2 extends in a front and back direction of a paper on which FIG. 2 is drawn. The body 2 is, for example, fixed to a ceiling in a room by using a plurality of screws (not illustrated).

The lighting-on device 3 is fixed to a middle section of the body 2 in a longitudinal direction. The lighting-on device 3 generates a DC output by receiving a commercial AC power supply and supplies the DC output to the straight tube type lamp 11 described below.

Moreover, the body 2 has a power supply terminal stand (not illustrated), a plurality of member support fittings, a pair of socket support members, and the like. A power supply line of the commercial AC power supply drawn from a ceiling is connected to the power supply terminal stand. Further, the power supply terminal stand is electrically connected to the lighting-on device 3 through a wiring (not illustrated) in the apparatus.

The socket 4a and the socket 4b are disposed in both end sections of the body 2 in the longitudinal direction by being respectively connected to the socket support members. The socket 4a and the socket 4b are mounted by rotation. For example, the socket 4a and the socket 4b are sockets suitable for G13 type mouthpieces 13a and 13b, respectively, which are included in the straight tube type lamp 11 described below.

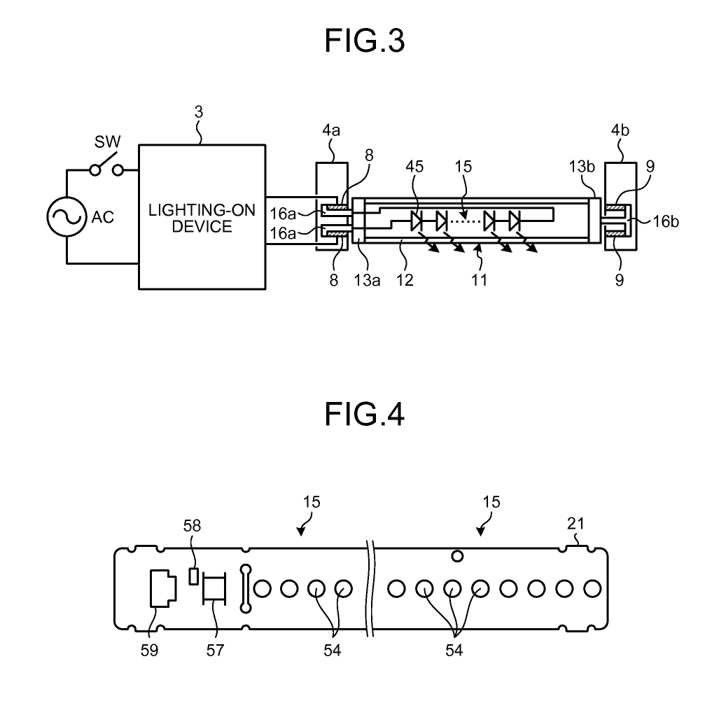

FIG. 3 is a conceptual view illustrating an example of an electrical connection relationship of the lighting device according to the first embodiment. As illustrated in FIG. 3, the socket 4a and the socket 4b have a pair of terminal fittings 8 and terminal fittings 9 to which lamp pins 16a and 16b (described below) are respectively connected. In order to supply the power supply to the straight tube type lamp 11 described below, the terminal fittings 8 of the first socket 4a are connected to the lighting-on device 3 through the wiring in the apparatus.

As illustrated in FIG. 2, for example, the reflection member 5 has a bottom plate section 5a, a side plate section 5b and an end plate 5c, which are made of metal and has a trough shape of which an upper surface is opened. The bottom plate section 5a is flat. The side plate section 5b is bent obliquely upward from the both ends of the bottom plate section 5a in a width direction. The end plate 5c closes an end surface opening formed by ends of the bottom plate section 5a and the side plate section 5b in the longitudinal direction.

A metal plate forming the bottom plate section 5a and the side plate section 5b is made of a color steel plate of which a surface has a white-based color. Thus, the surfaces of the bottom plate section 5a and the side plate section 5b are reflection surfaces. Socket holes (not illustrated) are formed on respective ends of the bottom plate section 5a in the longitudinal direction.

The reflection member 5 covers the body 2 and each component that is mounted on the body 2. The state is held by detachable decorative screws 6 (see FIG. 1). The decorative screw 6 is screwed upwardly into the member support fitting through the bottom plate section 5a. The decorative screw 6 may be operated by hand without using any tool. The socket 4a and the socket 4b protrude downward from the bottom plate section 5a through the socket holes.

In FIG. 1, the lighting device 1 supports one straight tube type lamp 11 described below, but, for example, may include two pairs of sockets to support two straight tube type lamps 11 as another form.

The straight tube type lamp 11 that is detachably supported by the socket 4a and the socket 4b is described below with reference to FIGS. 2 and 3. The straight tube type lamp 11 has dimensions and an outer diameter similar to those of the existing fluorescent lamp. The straight tube type lamp 11 includes a pipe 12, a first mouthpiece 13a and a second mouthpiece 13b which are mounted in both ends of the pipe 12, a beam 14 and a light emitting unit 15.

The pipe 12 is formed of a resin material having translucency, for example, in an elongated shape. As the resin material forming the pipe 12, a polycarbonate resin in which a light diffusion member is mixed can be preferably used. Diffuse transmittance of the pipe 12 is preferably 90% to 95%. As illustrated in FIG. 2, the pipe 12 has a pair of convex sections 12a on an inner surface of a portion that is an upper section when being used.

The first mouthpiece 13a is mounted on one end section of the pipe 12 in the longitudinal direction and the second mouthpiece 13b is mounted on the other end section of the pipe 12 in the longitudinal direction. The first mouthpiece 13a and second mouthpiece 13b are detachably connected to the socket 4a and the socket 4b, respectively. The straight tube type lamp 11 that is supported on the socket 4a and the socket 4b is disposed directly below the bottom plate section 5a of the reflection member 5 by the connection. A part of light that is emitted from the straight tube type lamp 11 to the outside is reflected from the side plate section 5b of the reflection member 5.

As illustrated in FIG. 3, the first mouthpiece 13a has two lamp pins 16a protruding to the outside thereof. The lamp pins 16a are electrically insulated from each other. In addition, leading ends of the two lamp pins 16a have L-shapes which are bent substantially at a right angle so as to separate from each other.

As illustrated in FIG. 3, the second mouthpiece 13b has one lamp pin 16b protruding to the outside thereof. The lamp pin 16b has a cylindrical shaft section and a leading end section which is provided in a leading end section of the cylindrical shaft section, and of which a shape of a front surface (not illustrated) has an elliptical shape or an oval shape, and a side surface of the lamp pin 16b has a T-shape.

The lamp pins 16a of the first mouthpiece 13a are connected to the terminal fittings 8 of the socket 4a and the lamp pin 16b of the second mouthpiece 13b is connected to the terminal fittings 9 of the socket 4b so that the straight tube type lamp 11 is mechanically supported on the socket 4a and the socket 4b. In a state of being supported, power is supplied to the straight tube type lamp 11 by the terminal fittings 8 inside the socket 4a and the lamp pins 16a of the first mouthpiece 13a connected thereto.

As illustrated in FIG. 2, the beam 14 is accommodated in the pipe 12. The beam 14 is a bar member having excellent mechanical strength and, for example, is formed of an aluminum alloy or the like for weight reduction. Both ends of the beam 14 in the longitudinal direction are connected to the first mouthpiece 13a and the second mouthpiece 13b by being electrically insulated. For example, the beam 14 has a plurality of substrate support sections 14a (one is illustrated in FIG. 2) having rib shapes.

FIG. 4 is a view illustrating an example of a configuration of the light emitting unit according to the first embodiment. As illustrated in FIG. 4, in the light emitting unit 15, a plurality of light emitting modules 54 are arranged on a substrate 21 in the longitudinal direction of the substrate 21, which is formed in an elongated substantially rectangular shape. Various electric components 57 to 59 such as a capacitor or a connector are disposed on the substrate 21. A surface of the substrate 21 has a resist layer mainly composed of a synthetic resin having high electric insulation. The resist layer is, for example, white and also functions as a reflective layer having high reflectance of light.

A length of the substrate 21 is substantially the same as an entire length of the beam 14. The substrate 21 is fixed by screws (not illustrated) which are screwed into the beam 14. In the embodiment, the light emitting unit 15 has one substrate 21, but the light emitting unit 15 may be configured of a plurality of substrates as another form.

The light emitting unit 15 and the beam 14 are accommodated in the pipe 12. In the state of being supported, both end sections of the light emitting unit 15 in the width direction are installed in the convex sections 12a of the pipe 12. Therefore, the light emitting unit 15 is disposed substantially horizontally on an upper side from the maximum width section inside the pipe 12.

### Configuration of Light Emitting Module 54

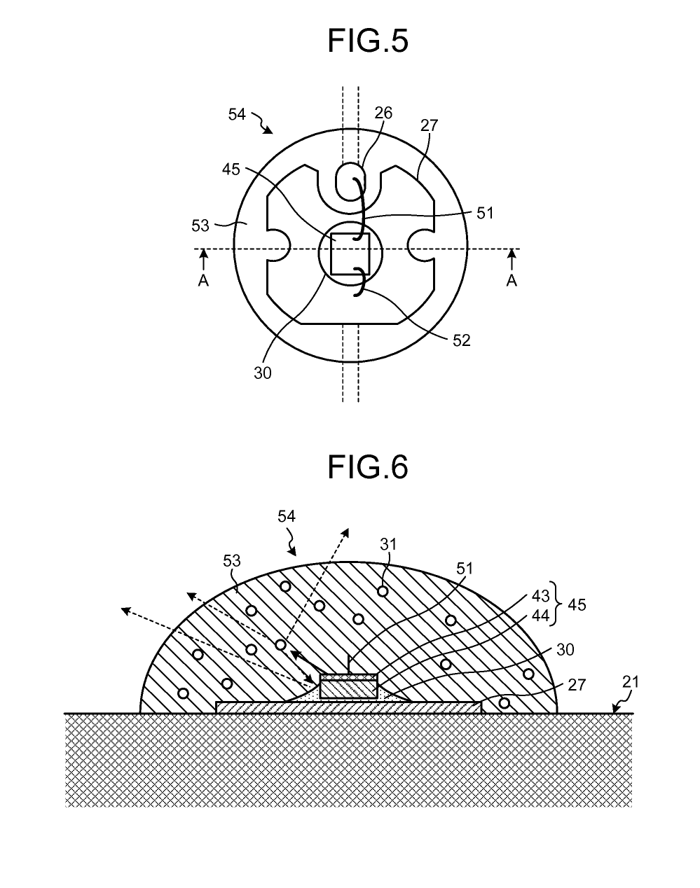

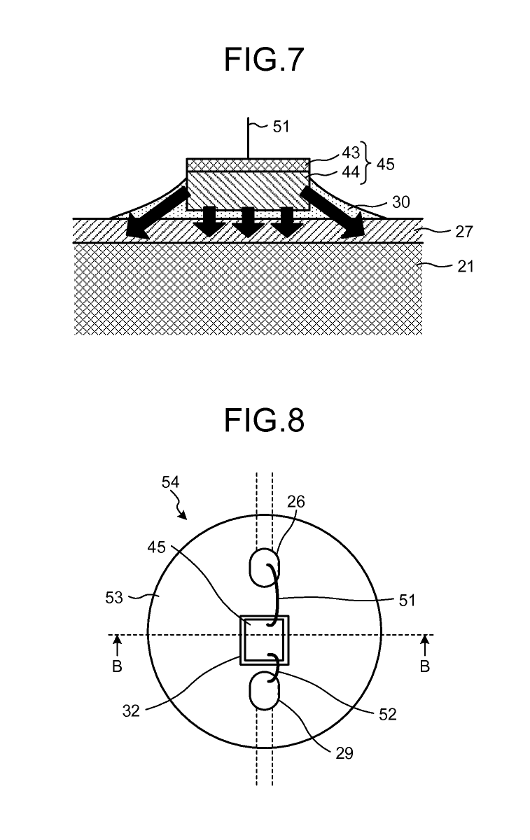

FIG. 5 is a top view illustrating an example of the light emitting module according to the first embodiment. FIG. 6 is a cross-sectional view of the light emitting module along A-A in FIG. 5. FIG. 7 is an enlarged view of the vicinity of an LED in FIG. 6.

The light emitting module 54 has an LED 45 and a sealing member 53. The LED 45 has a base material 44 that is formed of silicon or a material containing silicon and a semiconductor layer (a light emitting layer) 43 that is formed on the base material 44 and contains gallium nitride (GaN) or the like. In the embodiment, for example, the base material 44 is formed in a six-sided shape. The base material 44 is bonded on a second wiring pad 27 by adhesive 30. In the embodiment, the adhesive 30 is configured of a material having high reflectance (for example, the reflectance is 60% or greater) such as that with a white or silver color.

An anode electrode and a cathode electrode are formed in the light emitting layer 43. The anode electrode of the light emitting layer 43 is wire-bonded to a first wiring pad 26 by a metal wire 51 such as gold. Further, the cathode electrode of the light emitting layer 43 is wire-bonded to the second wiring pad 27 by a metal wire 52 such as gold. For example, surfaces of the first wiring pad 26 and the second wiring pad 27 are plated with a material having high reflectance such as silver.

For example, the sealing member 53 is a transparent thermoplastic resin having high diffusion, such as an epoxy resin, a urea resin, and a silicon resin to which phosphors 31 are added. The phosphor 31 is excited by the light emitted from the light emitting layer 43 of the LED 45 and then radiates the light of a color that is different from a color of the light emitted from the light emitting layer 43.

In the embodiment, as the phosphor 31, a yellow phosphor is used which radiates yellow-based light that has a complementary color to blue light by being excited by the blue light emitted from the light emitting layer 43. Therefore, the light emitting module 54 can emit white light as output light.

In the embodiment, since the base material 44 is formed of silicon, a surface of the base material 44 is black and absorbs the light. Thus, the light among the light emitted from the light emitting layer 43, which is emitted from the surface of the light emitting layer 43 in contact with the base material 44, is absorbed by the base material 44 and is not emitted to the outside. Therefore, the light emitting layer 43 mainly emits the light above the base material 44.

Here, since the base material 44 is black and absorbs the light, when the base material 44 is exposed to the inside of the sealing member 53, if the light from the light emitting layer 43 is incident on a direction of the base material 44 by being reflected from a boundary surface of the sealing member 53 or if a part of the light that is emitted from the phosphor 31 by receiving the light from the light emitting layer 43 is incident on the direction of the base material 44, the base material 44 absorbs each light.

If a part of the light emitted from the light emitting layer 43 is absorbed by the base material 44, the light is not emitted to the outside of the sealing member 53 and luminous efficiency of the light emitting module 54 is lowered. Therefore, in order to reduce an amount of the light incident on the base material 44, it is preferable that an area of a surface in which the base material 44 is exposed to the inside of the light emitting module 54 be reduced in terms of improvement in the luminous efficiency.

In the embodiment, for example, as illustrated in FIGS. 5 to 7, the adhesive 30 covers two surfaces or more (in the embodiment, a total five surfaces of a bottom surface and side surfaces of the base material 44) of the base material 44 besides a surface on which the light emitting layer 43 is provided. For example, as illustrated in FIGS. 5 to 7, the adhesive 30 covers an area of half or more for each of the five surfaces of the base material 44 besides the surface on which the light emitting layer 43 is provided.

The adhesive 30 is configured of a material that is not transparent. Thus, the adhesive 30 prevents (suppresses) the light among the light from the light emitting layer 43, which is reflected from the boundary surface of the sealing member 53 or prevents a part of the light which is emitted from the phosphor 31 by receiving the light from the light emitting layer 43, from being incident on the base material 44. Therefore, the adhesive 30 can reduce the amount of the light among the light emitted from the light emitting layer 43, which is absorbed by the base material 44. Therefore, it is possible to expect improvement in the luminous efficiency of the LED 45.

Moreover, in the LED 45 according to the embodiment, since silicon is used in the base material 44, the light emitted from a lower surface of the light emitting layer 43 is not emitted to the outside by being absorbed by the base material 44. Thus, the adhesive 30 covering the bottom surface and the side surfaces of the base material 44 does not affect the luminous efficiency of the LED 45, even if a material without translucency is used.

Further, in the embodiment, since the adhesive 30 is not necessary transparent, for example, a material having high reflectance such as alumina or titania can be added to the adhesive 30. Since the adhesive 30 has high reflectance, the light incident on the direction of the base material 44 is reflected from the surface of the adhesive 30 and is emitted to the outside of the light emitting module 54. Therefore, it is possible to expect the improvement in the luminous efficiency of the light emitting module 54.

Moreover, the surfaces of the first wiring pad 26 and the second wiring pad 27 are plated with a material having high reflectance such as silver, and a white resist layer having high reflectance is provided on the surface of the substrate 21. Thus, the light that is scattered in the sealing member 53 is also emitted to the outside of the light emitting module 54 by being reflected from those regions inside the light emitting module 54.

Further, since the adhesive 30 may not be transparent, a material that improves the thermal conductivity in addition to the reflectance can be added to the adhesive 30. The adhesive 30 is in contact with the base material 44 so as to cover the five surfaces besides the surface on which the light emitting layer 43 is provided. Thus, for example, as illustrated by arrows in FIG. 7, heat that is generated by the light emitting layer 43 and transferred to the base material 44 is respectively transferred to the adhesive 30 from four side surfaces as well as from the bottom surface of the base material 44. Then, for example, as illustrated by the arrows in FIG. 7, the heat that is transferred from the base material 44 to the adhesive 30 is efficiently radiated to the substrate 21.

Here, in the LED of the related art in which the base material is formed of a transparent material such as sapphire, the light that is emitted from the bottom surface of the light emitting layer 43 is emitted to the outside of the LED 45 by passing through the transparent base material. Thus, since the adhesive bonding the base material to the second wiring pad 27 shields the light passing through the base material, the adhesive cannot widely cover the side surfaces of the base material.

On the other hand, in the LED 45 according to the embodiment, since a black member that is not transparent such as silicon is used in the base material 44, even if the adhesive 30 that is not transparent widely covers the side surfaces of the base material 44, the adhesive 30 does not affect the luminous efficiency of the LED 45. Thus, the adhesive 30 can widely cover the side surfaces of the base material 44. Therefore, the heat that is generated by the light emitting layer 43 and transferred to the base material 44 is efficiently transferred to the adhesive 30. Then, the adhesive 30 efficiently transfers the heat that is generated in the LED 45 to the substrate 21 through the second wiring pad 27 by employing the material having high thermal conductivity in the adhesive 30.

Further, since the adhesive 30 may not be transparent, for example, there is no need to consider the translucency of the light for the adhesive 30 and a material having high reflectance and high thermal conductivity such as alumina or titania can be added to the adhesive 30. Moreover, in the embodiment, it is preferable that the thermal conductivity of the adhesive 30 be 0.3 W/mK or greater.

Moreover, in the light emitting module 54 according to the embodiment, the adhesive 30 covers the five surfaces besides the surface on which the light emitting layer 43 is provided in the base material 44, but the example is not limited to the embodiment and the adhesive 30 may cover half or more of one surface, two surfaces or three surfaces in the side surfaces of the base material 44. Also, in this case, since the adhesive 30 having high thermal conductivity can widely cover the side surfaces of the base material, the heat that is generated in the LED 45 can be efficiently transferred to the substrate 21 through the adhesive 30 compared to the LED of the related art in which a transparent material is used in the base material.

The first embodiment is described above.

As is apparent from the above description, according to the light emitting module 54 of the embodiment, it is possible to expect the improvement in the luminous efficiency of the light emitting module 54. Further, according to the light emitting module 54 of the embodiment, it is possible to expect that the heat that is generated in the LED 45 is efficiently radiated to the substrate 21.

### Second Embodiment

Next, a second embodiment is described with reference to the drawings. In the embodiment, since the configurations of a lighting device 1, a straight tube type lamp 11 and a light emitting unit 15 are similar to the lighting device 1, the straight tube type lamp 11 and the light emitting unit 15 of the first embodiment, detailed description thereof is omitted.

### Configuration of Light Emitting Module 54

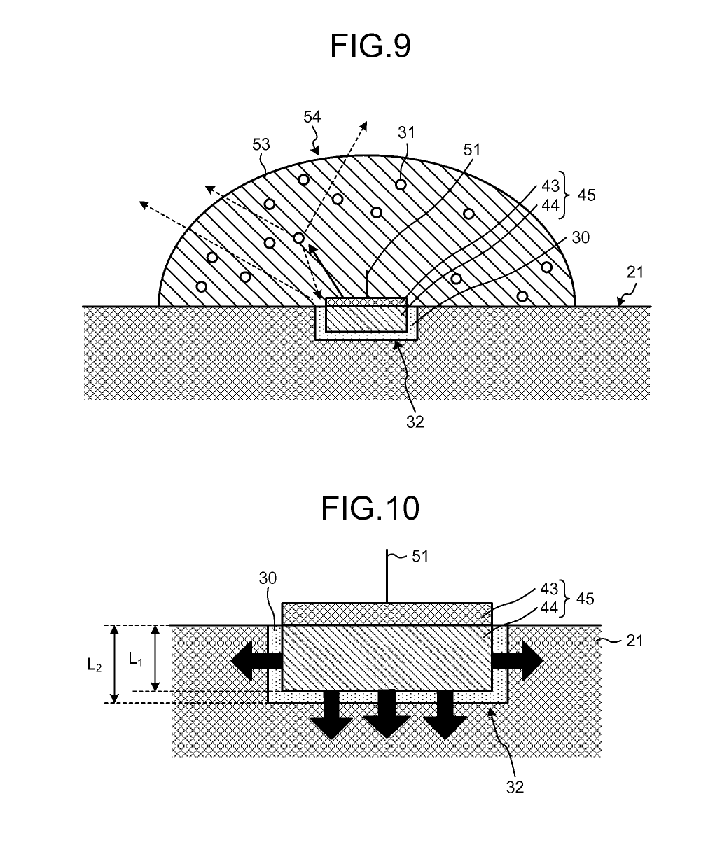

FIG. 8 is a top view illustrating an example of a light emitting module according to the second embodiment. FIG. 9 is a cross-sectional view of the light emitting module along B-B in FIG. 8. FIG. 10 is an enlarged view of the vicinity of an LED in FIG. 9. Moreover, since configurations to which the same symbols as those in FIGS. 5 to 7 are given in FIGS. 8 to 10 are the same as the configurations or have similar functions in FIGS. 5 to 7, the description thereof is omitted with exception that is described below.

A concave section 32 that has substantially the same shape as that of the base material 44 and is a recess that is slightly greater than an external shape of the base material 44 in a thickness direction of the substrate 21 is provided in the substrate 21. The LED 45 is fitted into the concave section 32 as the light emitting layer 43 up and the bottom surface and the side surfaces of the base material 44 are bonded to a bottom and an inner wall of the concave section 32 with the adhesive 30. Also in the embodiment, it is preferable that the adhesive 30 be configured of a material having high reflectance.

The anode electrode of the light emitting layer 43 is wire-bonded to the first wiring pad 26 by the metal wire 51 such as gold and the cathode electrode of the light emitting layer 43 is wire-bonded to a second wiring pad 29 by the metal wire 52 such as gold. For example, a surface of the second wiring pad 29 is also plated by a material having high reflectance such as silver.

In the embodiment, for example, as illustrated in FIG. 10, the concave section 32 is formed on the substrate 21 so that a length L₂ of the concave section 32 in the thickness direction of the substrate 21 is longer than a length of half of a thickness L₁ of the base material 44. In the embodiment, the concave section 32 is formed on the substrate 21 so that the depth L₂ is substantially the same as a length that is obtained by adding the thickness L₁ of the base material 44 and the thickness of the adhesive 30 in contact with the bottom surface of the base material 44. Therefore, the inner wall of the concave section 32 can further widely cover the side surfaces of the base material 44 through the adhesive 30 and the light that is emitted from the light emitting layer 43 is emitted into the sealing member 53 without being shielded by the inner wall of the concave section 32.

Also in the embodiment, a resist layer having high reflectance is provided on the surface of the substrate 21. Thus, the surface of the substrate 21 around the concave section 32 prevents (suppresses) the light that is reflected from the boundary surface of the sealing member 53 by being emitted from the light emitting layer 43 or prevents a part of the light that is emitted from the phosphor 31 by receiving the light from the light emitting layer 43 from being incident on the base material 44. Therefore, the substrate 21 can reduce the amount of the light among the light emitted from the light emitting layer 43, which is absorbed by the base material 44. Therefore, it is possible to expect the improvement in the luminous efficiency of the LED 45.

In the embodiment, for example, as illustrated in FIGS. 8 to 10, the inner wall of the concave section 32 covers two surfaces or more (in the embodiment, five surfaces) of the base material 44 besides a surface on which the light emitting layer 43 is provided. Further, for example, as illustrated in FIGS. 8 to 10, the inner wall of the concave section 32 covers an area of half or more of each of the five surfaces of the base material 44 besides the surface on which the light emitting layer 43 is provided. Therefore, the concave section 32 can reduce an area in which the side surfaces of the base material 44 are exposed to the inside of the sealing member 53 and it is possible to expect the improvement in the luminous efficiency of the LED 45.

Further, in the embodiment, the adhesive 30 is configured of a material having high reflectance and the resist layer having high reflectance is provided on the surface of the substrate 21. Thus, the light incident on the direction of the base material 44 is reflected from the surface of the adhesive 30 or the surface of the substrate 21 in the vicinity of the concave section 32, and is emitted to the outside of the light emitting module 54. Therefore, it is possible to expect the improvement in the luminous efficiency of the light emitting module 54.

Further, the inner wall of the concave section 32 covers the five surfaces of the base material 44 besides the surface on which the light emitting layer 43 is provided, and the base material 44 and the concave section 32 are bonded with the adhesive 30 having high thermal conductivity. Thus, for example, as illustrated by arrows in FIG. 10, heat that is generated by the light emitting layer 43 and transferred to the base material 44 is respectively transferred to the adhesive 30 from four side surfaces of the base material 44 as well as from the bottom surface of the base material 44. Then, for example, as illustrated by the arrows in FIG. 10, the heat that is transferred from the base material 44 to the adhesive 30 is efficiently radiated to the substrate 21 through the inner wall of the concave section 32.

As described above, also in the embodiment, the heat that is generated by the light emitting layer 43 and transferred to the base material 44 is efficiently transferred to the adhesive 30 by widely covering the side surfaces of the base material 44 with the adhesive 30 and the inner wall of the concave section 32. Then, it is possible to efficiently transfer the heat that is generated in the LED 45 to the substrate 21 through the inner wall of the concave section 32 by employing a material having high thermal conductivity in the adhesive 30.

Moreover, in the light emitting module 54 according to the embodiment, the concave section 32 has substantially the same shape as that of the base material 44 in the thickness direction of the substrate 21 and has a shape slightly greater than the external shape of the base material 44, but the example is not limited to the embodiment. For example, a groove that has a width substantially the same as the width of the base material 44 and has a depth of half or more of the thickness of the base material 44 is provided in the substrate 21 in the thickness direction of the substrate 21 and the LED 45 may be fitted into the groove as the light emitting layer up. Also in this case, it is possible to efficiently transfer the heat that is generated in the light emitting layer 43 from the inner wall of the groove in contact with the side surfaces of the base material 44 to the substrate 21 through the adhesive 30.

The second embodiment is described above.

As is apparent from the above description, also in the light emitting module 54 of the embodiment, it is possible to expect the improvement in the luminous efficiency of the light emitting module 54. Further, also in the light emitting module 54 of the embodiment, it is possible to expect that the heat that is generated in the LED 45 is efficiently radiated to the substrate 21.

### Third Embodiment

Next, a third embodiment is described with reference to the drawings. In the embodiment, since the configurations of a lighting device 1, a straight tube type lamp 11 and a light emitting unit 15 are similar to the lighting device 1, the straight tube type lamp 11 and the light emitting unit 15 of the first embodiment, detailed description thereof is omitted.

### Configuration of Light Emitting Module 54

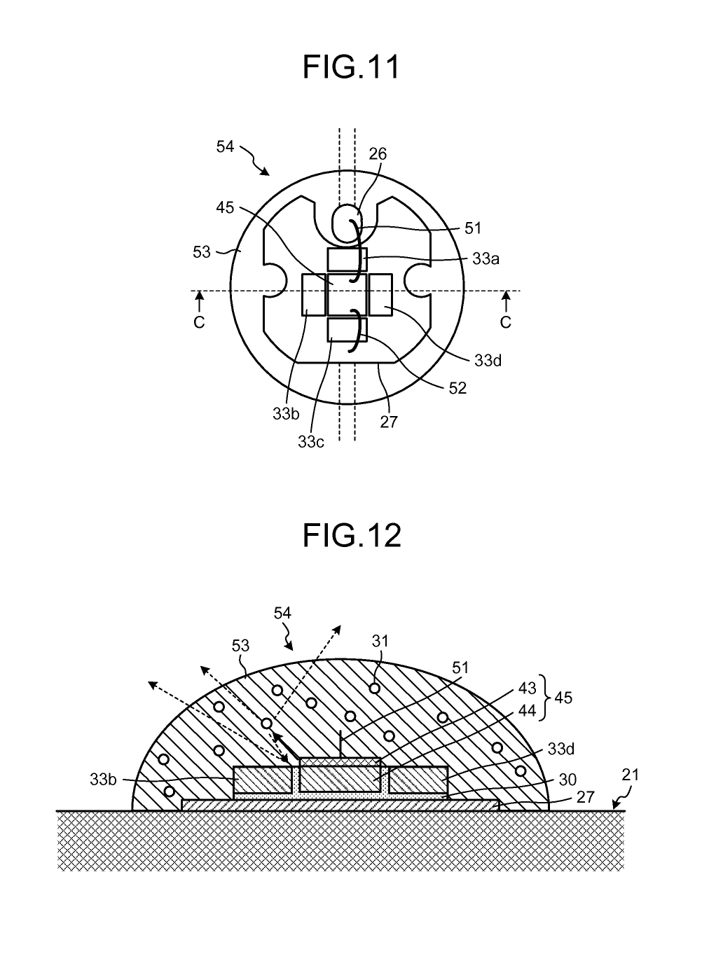

FIG. 11 is a top view illustrating an example of a light emitting module according to the third embodiment. FIG. 12 is a cross-sectional view of the light emitting module along C-C in FIG. 11. Moreover, since configurations to which the same symbols as those in FIGS. 5 and 6 are given in FIGS. 11 and 12 are the same as the configurations or have similar functions in FIGS. 5 and 6, the description thereof is omitted with exception that is described below.

Four structures 33a to 33d, which are formed of a material having high thermal conductivity and have substantially the same thickness as that of the base material 44, are provided around the LED 45 so as to surround the LED 45 on the second wiring pad 27. One surface of each of the structures 33a to 33d is bonded to the side surface of the base material 44 by the adhesive 30, and another surface is bonded to the substrate 21 by the adhesive 30. Also in the embodiment, it is preferable that the adhesive 30 be configured of a material having high thermal conductivity.

In the embodiment, the resist layer having high reflectance is provided on the surface of each of the structures 33a to 33d. Thus, the surface of each of the structures 33a to 33d prevents (suppresses) the light that is reflected from the boundary surface of the sealing member 53 by being emitted from the light emitting layer 43 or prevents a part of the light that is emitted from the phosphor 31 by receiving the light from the light emitting layer 43 from being incident on the base material 44. Also in the embodiment, two surfaces or more (in the embodiment, four surfaces) of the base material 44 besides a surface on which the light emitting layer 43 is provided are covered by a plurality of structures 33. Further, an area of half or more of each of side surfaces of the base material 44 is covered by the structures 33.

Further, in the embodiment, the resist layer having high reflectance is provided on the surface of each of the structures 33. Thus, the light incident on the direction of the base material 44 is reflected from the surface of each of the structures 33a to 33d and is emitted to the outside of the light emitting module 54.

Further, each of the structures 33a to 33d covers each of the side surfaces of the base material 44, and the side surface of the base material 44 and the surface of each of the structures 33a to 33d are bonded with the adhesive 30 having high thermal conductivity. Thus, the heat that is generated by the light emitting layer 43 and transferred to the base material 44 is efficiently transferred from the side surfaces of the base material 44 to each of the structures 33a to 33d through the adhesive 30. Then, each of the structures 33a to 33d radiates the heat that is transferred from the base material 44 to the second wiring pad 27 and the substrate 21 through the adhesive 30. Therefore, it is possible to expect that each of the structures 33a to 33d efficiently radiates the heat that is generated in the LED 45 to the substrate 21.

Moreover, in the light emitting module 54 according to the embodiment, four structures 33 are disposed around the LED 45, but the example is not limited to the embodiment and one, two or three structures 33 may be disposed around the LED 45. Further, two, three or four structures 33 may be integrally formed.

The third embodiment is described above.

As is apparent from the above description, also in the light emitting module 54 of the embodiment, it is possible to expect the improvement in the luminous efficiency of the light emitting module 54. Further, also in the light emitting module 54 of the embodiment, it is possible to expect that the heat that is generated in the LED 45 is efficiently radiated to the substrate 21.

### Fourth Embodiment

Next, a fourth embodiment is described with reference to the drawing. In the embodiment, since the configurations of a lighting device 1, a straight tube type lamp 11 and a light emitting unit 15 are similar to the lighting device 1, the straight tube type lamp 11 and the light emitting unit 15 of the first embodiment, detailed description thereof is omitted.

### Configuration of Light Emitting Module 54

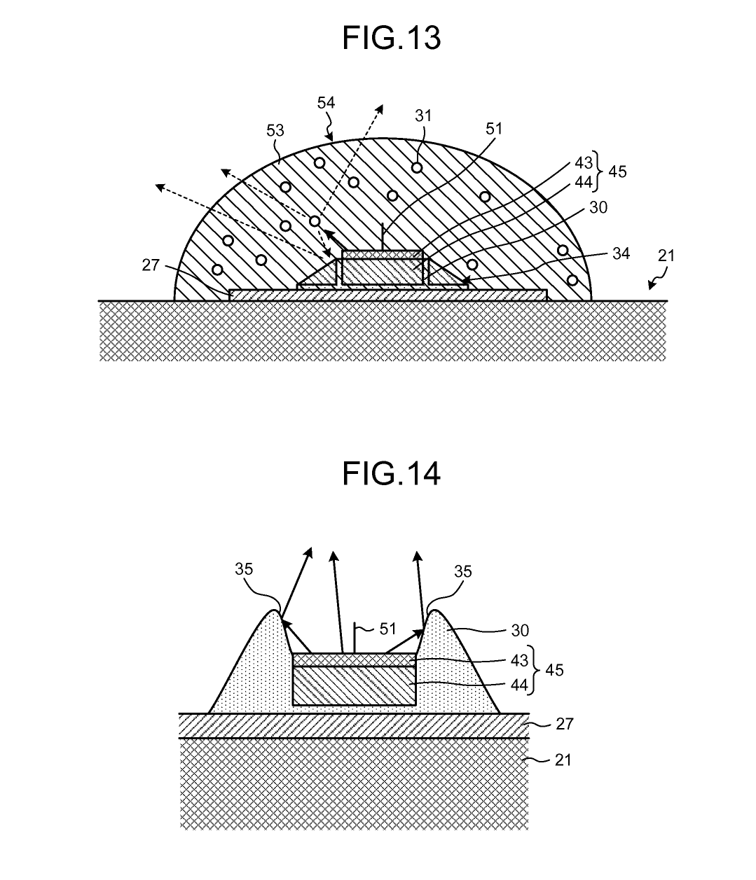

FIG. 13 is a cross-sectional view of an example of a light emitting module according to the fourth embodiment. Moreover, since configurations to which the same symbols as those in FIG. 6 are given in FIG. 13 are the same as the configurations or have similar functions in FIG. 6, the description thereof is omitted with exception that is described below.

Structures 34 which are formed of a material having high thermal conductivity are provided around the LED 45 so as to surround the LED 45 on the second wiring pad 27. For example, a cross section of each of the structures 34 is formed in a triangular prism shape that is substantially a right-angled triangle. Thus, one surface of each of the structures 34 is bonded to the side surface of the base material 44 by the adhesive 30 and another surface is bonded to the substrate 21 by the adhesive 30. Also in the embodiment, it is preferable that the adhesive 30 be configured of a material having high thermal conductivity.

In the embodiment, the resist layer having high reflectance is provided on the surface of each of the structures 34. Thus, the surface of each of the structures 34 prevents (suppresses) the light that is reflected from the boundary surface of the sealing member 53 by being emitted from the light emitting layer 43 or prevents a part of the light that is emitted from the phosphor 31 by receiving the light from the light emitting layer 43 from being incident on the base material 44. Also in the embodiment, two surfaces or more (in the embodiment, four surfaces) of the base material 44 besides a surface on which the light emitting layer 43 is provided are covered by a plurality of structures 34. Further, an area of half or more of each of side surfaces of the base material 44 is covered by each of the surfaces of the structures 34.

Further, in the embodiment, the resist layer having high reflectance is provided on the surface of each of the structures 34. Thus, the light incident on the direction of the base material 44 is reflected from the surface of each of the structures 34 and is emitted to the outside of the light emitting module 54.

Further, each of the structures 34 covers each of the side surfaces of the base material 44, and the side surface of the base material 44 and the surface of each of the structures 34 are bonded with the adhesive 30 having high thermal conductivity. Thus, the heat that is generated by the light emitting layer 43 and transferred to the base material 44 is efficiently transferred from the side surfaces of the base material 44 to each of the structures 34 through the adhesive 30. Then, each of the structures 34 radiates the heat that is transferred from the base material 44 to the second wiring pad 27 and the substrate 21 through the adhesive 30. Therefore, it is possible to expect that each of the structures 34 efficiently radiates the heat that is generated in the LED 45 to the substrate 21.

Moreover, in the light emitting module 54 according to the embodiment, four structures 34 are disposed around the LED 45, but the example is not limited to the embodiment and one, two or three structures 34 may be disposed around the LED 45. Further, two, three or four structures 34 may be integrally formed.

The fourth embodiment is described above.

As is apparent from the above description, also in the light emitting module 54 of the embodiment, it is possible to expect the improvement in the luminous efficiency of the light emitting module 54. Further, also in the light emitting module 54 of the embodiment, it is possible to expect that the heat that is generated in the LED 45 is efficiently radiated to the substrate 21.

### Fifth Embodiment

Next, a fifth embodiment is described with reference to the drawing. In the embodiment, since the configurations of a lighting device 1, a straight tube type lamp 11 and a light emitting unit 15 are similar to the lighting device 1, the straight tube type lamp 11 and the light emitting unit 15 of the first embodiment, detailed description thereof is omitted. Configuration of Light Emitting Module 54

FIG. 14 is a view of an example of the vicinity of an LED according to the fifth embodiment. Moreover, since configurations to which the same symbols as those in FIG. 7 are given in FIG. 14 are the same configurations or have similar functions in FIG. 7, the description thereof is omitted with exception that is described below.

In the embodiment, the adhesive 30 is formed around the LED 45 so as to be higher than a total height of the LED 45 and to surround the LED 45. For example, as illustrated in FIG. 14, the adhesive 30 is formed so that a length thereof in the thickness direction of the substrate is longer than a length that is obtained by adding a thickness of the base material and a thickness of the light emitting layer. Also in the embodiment, the adhesive 30 is configured of a material having high reflectance.

Therefore, a part of the light that is emitted from the light emitting layer 43 is reflected from a surface 35 of the adhesive 30 formed above the upper surface of the light emitting layer 43 and is emitted above the light emitting layer 43. Therefore, the adhesive 30 suppresses the diffusion of the light that is emitted by the light emitting layer 43 and it is possible to enhance directivity of the light that is emitted from the LED 45. Further, it is possible to control light distribution of the LED 45 by adjusting an angle of the surface 35 of the adhesive 30 facing the light emitting layer 43.

If the light distribution is controlled as an entirety of the lighting device 1, an optical member for the control of the light distribution may be provided outside the light emitting module 54, but there is a problem in that the size or the cost of the device increases. On the other hand, in the light emitting module 54 according to the embodiment, since the control of the light distribution can be performed inside the light emitting module 54, it is possible to reduce the size, the cost, the weight or the like of the device.

The fifth embodiment is described above.

### Sixth Embodiment

Next, a sixth embodiment is described with reference to the drawing. In the embodiment, since the configurations of a lighting device 1, a straight tube type lamp 11 and a light emitting unit 15 are similar to the lighting device 1, the straight tube type lamp 11 and the light emitting unit 15 of the first embodiment, detailed description thereof is omitted.

### Configuration of Light Emitting Module 54

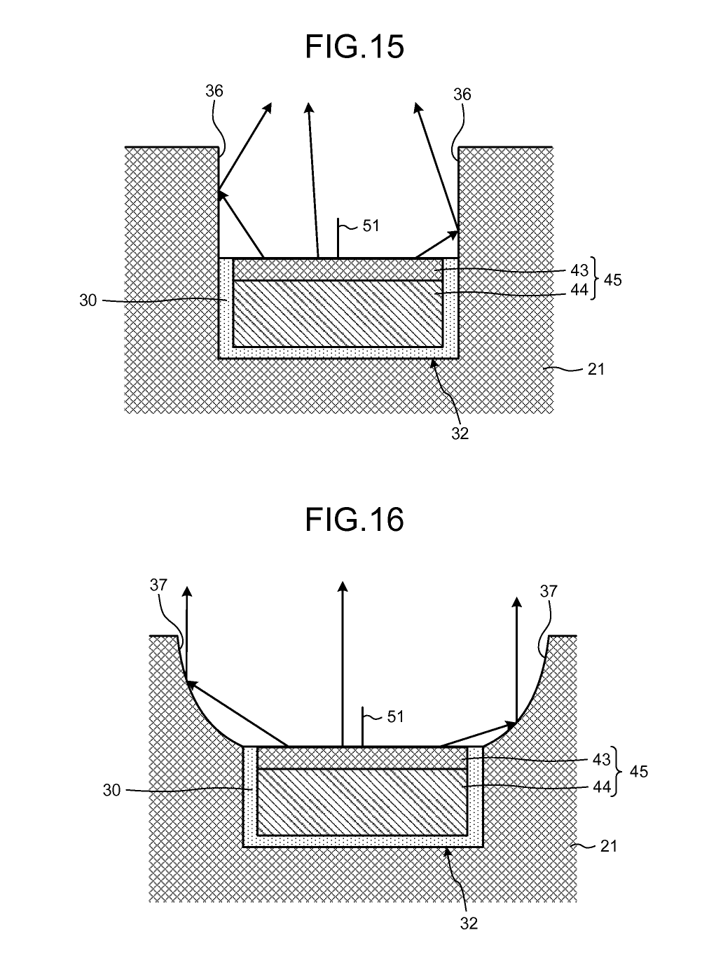

FIG. 15 is a view of an example of the vicinity of an LED according to the sixth embodiment. Moreover, since configurations to which the same symbols as those in FIG. 10 are given in FIG. 15 are the same as the configurations or have similar functions in FIG. 10, the description thereof is omitted with exception that is described below.

In the embodiment, the concave section 32 is formed on the substrate 21 so as to be deeper than a total height of the LED 45. In the embodiment, for example, a surface 36 of the inner wall of the concave section 32 is covered by the resist layer having high reflectance. Therefore, a part of the light that is emitted from the light emitting layer 43 is reflected from the surface 36 of the inner wall of the concave section 32 and is emitted above the light emitting layer 43. Therefore, the concave section 32 suppresses the diffusion of the light that is emitted by the light emitting layer 43 and it is possible to enhance directivity of the light that is emitted from the LED 45. Further, it is possible to control the light distribution of the LED 45 by adjusting an angle of the surface 36 of the inner wall of the concave section 32 facing the light emitting layer 43.

The sixth embodiment is described above.

### Seventh Embodiment

Next, a seventh embodiment is described with reference to the drawing. In the embodiment, since the configurations of a lighting device 1, a straight tube type lamp 11 and a light emitting unit 15 are similar to the lighting device 1, the straight tube type lamp 11 and the light emitting unit 15 of the first embodiment, detailed description thereof is omitted.

### Configuration of Light Emitting Module 54

FIG. 16 is a view of an example of the vicinity of an LED according to the seventh embodiment. Moreover, since configurations to which the same symbols as those in FIG. 10 are given in FIG. 16 are the same as the configurations or have similar functions in FIG. 10, the description thereof is omitted with exception that is described below.

In the embodiment, the concave section 32 is formed on the substrate 21 so as to be deeper than a total height of the LED 45. In the embodiment, a surface 37 of the inner wall of the concave section 32 is formed in a bowl shape of which an opening is gradually increased advancing from a position of the upper surface of the light emitting layer 43 to an end of the opening of the concave section 32 in the thickness direction of the substrate 21, in a state where the LED 45 is fitted into the concave section 32. For example, the surface 37 of the inner wall of the concave section 32 may be formed in a parabolic shape in which a direction of the bottom of the concave section 32 is convex.

In the embodiment, for example, the surface 37 of the bowl shape in the concave section 32 is covered by the resist layer having high reflectance. Therefore, a part of the light that is emitted from the light emitting layer 43 is reflected from the surface 37 of the inner wall of the concave section 32 and is emitted above the light emitting layer 43. Therefore, the concave section 32 suppresses the diffusion of the light that is emitted by the light emitting layer 43 and it is possible to enhance directivity of the light that is emitted from the LED 45. Further, it is possible to control the light distribution of the LED 45 by adjusting an angle of the surface 37 of the inner wall of the concave section 32 facing the light emitting layer 43.

The seventh embodiment is described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light emitting module comprising:
a semiconductor light emitting element configured to include a base material that is formed of a material absorbing light and is provided on a substrate, and a light emitting layer that is provided on the base material and emits the light; and
an incident suppression section configured to be provided around the base material and suppress light among the light that is emitted from the light emitting layer from being incident on the base material.

2. The module according to claim 1,
wherein the incident suppression section is white adhesive that bonds the base material on the substrate, and
wherein the adhesive is in contact with side surfaces of the base material so as to cover the side surfaces of the base material.

3. The module according to claim 2,
wherein the adhesive covers an area of half or more of the side surfaces of the base material.

4. The module according to claim 2,
wherein in a state where the adhesive bonds the base material and the substrate, a length of the adhesive around the base material in a thickness direction of the substrate is longer than a length that is obtained by adding a thickness of the base material and a thickness of the light emitting layer.

5. The module according to claim 3,
wherein in a state where the adhesive bonds the base material and the substrate, a length of the adhesive around the base material in a thickness direction of the substrate is longer than a length that is obtained by adding a thickness of the base material and a thickness of the light emitting layer.

6. The module according to claim 1,
wherein the incident suppression section is a substrate that has a concave section into which the base material is fitted.

7. The module according to claim 6,
wherein a length of the concave section in the thickness direction of the substrate is longer than a length of half of a thickness of the base material.

8. A lighting device comprising:
a light emitting module; and
a lighting-on device configured to supply electric power to the light emitting module,
wherein the light emitting module includes
a semiconductor light emitting element configured to include a base material that is formed of a material absorbing light and is provided on a substrate, and a light emitting layer that is provided on the base material and emits the light, and
an incident suppression section configured to be provided around the base material and suppress light among the light that is emitted from the light emitting layer from being incident on the base material.

9. The device according to claim 8,
wherein the incident suppression section is white adhesive that bonds the base material on the substrate, and
wherein the adhesive is in contact with side surfaces of the base material so as to cover the side surfaces.

10. The device according to claim 9,
wherein the adhesive covers an area of half or more of the side surfaces of the base material.

11. The device according to claim 9,
wherein in a state where the adhesive bonds the base material and the substrate, a length of the adhesive around the base material in a thickness direction of the substrate is longer than a length that is obtained by adding a thickness of the base material and a thickness of the light emitting layer.

12. The device according to claim 10,
wherein in a state where the adhesive bonds the base material and the substrate, a length of the adhesive around the base material in a thickness direction of the substrate is longer than a length that is obtained by adding a thickness of the base material and a thickness of the light emitting layer.

13. The device according to claim 8,
wherein the incident suppression section is a substrate that has a concave section into which the base material is fitted.

14. The device according to claim 13,
wherein a length of the concave section in a thickness direction of the substrate is longer than a length of half of a thickness of the base material.
